(19) United States
(12) Patent Application Publication
(10) Pub. No.: US 2009/0030623 A1
(43) Pub. Date: Jan. 29, 2009

(54) SYSTEM AND METHOD OF DETERMINING THE AREA OF VULNERABILITY FOR ESTIMATION OF VOLTAGE SAGS AND COMPUTER-READABLE MEDIUM HAVING EMBODIED THEREON COMPUTER PROGRAM FOR THE METHOD

(75) Inventors: Gil-Soo Jang, Seoul (KR); Chang-Hyun Park, Seoul (KR)

Correspondence Address: CANTOR COLBURN, LLP, 20 Church Street, 22nd Floor, Hartford, CT, 06103, US

(73) Assignee: Korea University Industry & Academy Collaboration Foundation, Seoul (KR)

(21) Appl. No.: 12/032,235

(22) Filed: Feb. 15, 2008

(30) Foreign Application Priority Data
Jul. 23, 2007 (KR) 10-2007-0073719

(51) Int. Cl. G01R 31/40

(52) U.S. Cl. 702/59

(57) ABSTRACT

Provided is a system for determining the area of vulnerability for estimation of voltage sages including: a system information reader reading information on a power system; a unit for determining the area of vulnerability calculating a voltages at a target bus corresponding to ends of a fault line by using the system information and a first residual voltage equation that is a voltage relationship between points in the fault line in the power system where a fault is simulated and the target bus where a voltage change due to the fault occurs, calculating a voltage at the target bus corresponding to a point between the ends when the voltages at the target bus corresponding to the ends are not higher than a predetermined voltage threshold, deriving a second residual voltage equation that is an approximate quadratic interpolation equation for the first residual voltage equation by using the voltages at the target bus corresponding to the ends and the point between the ends of the fault line, calculating the voltage of the target bus corresponding to the point of the fault line by using the second residual voltage equation, and determining the point of the fault line corresponding to a voltage of the target bus equal to or lower than the predetermined voltage threshold as the area of vulnerability; and a result output unit outputting results of the determination of the area of vulnerability.

### BACKGROUND OF THE INVENTION

1. Field of the Invention

The present invention relates to a power system, and more particularly, to a system and method for improving power-quality.

2. Description of the Related Art

Voltage sags are one of the most important power-quality (PQ) problems and known as voltage dips during a short time. According to IEEE Standard 1159-1995, a voltage is the decrease in rms voltage between 0.1 and 0.9 p.u. at the power frequency for durations from 0.5 cycles to 1 min. Voltage sags are mainly caused by faults in a power system.

When a fault occurs, a voltage in the system decreases, and loads sensitive to the change in the voltage may misoperate or stop operating. As the loads sensitive to the change in the voltage have been increasingly used, financial losses due to voltage sags increase.

Voltage magnitude and duration are essential characteristics of a voltage sag. The voltage sag magnitude mainly depends on not only the fault location and the configuration of the power system, but also on some other factors such as fault type, the prefault voltage, transformer connection, and fault impedance. The voltage sag magnitude is expressed as rms voltage in percent or per unit and calculated by short-circuit analysis.

The voltage sag duration is defined as the flow duration of the fault current in a system where the fault occurs. Therefore, the duration is determined by the characteristics of the system protection devices such as overcurrent relays, circuit breakers and fuses. Generally, the duration is calculated by adding the intentional time delay considering protection coordination to the fault clearing time of each device.

For estimation of voltage sags, the accurate calculation of the area of vulnerability for a sensitive load is important. The area of vulnerability is a critical point (referred to as a fault location) at a load bus where voltage sags occur. The calculation of the area of the vulnerability is finding all fault locations. By calculating the accurate area of vulnerability, the expected sag frequency (ESF) at a target bus can be predicted.

For example, if a sensitive load misoperates or stops operating due to a voltage sag of 0.8 p.u. or less, a voltage threshold of the load is 0.8 p.u., and as the area of the vulnerability for the corresponding load, fault locations in a system that lead to voltages of buses connected to the load lower than 0.8 p.u. are found.

Two methods have been given for the determination of the area of vulnerability.

The first method is the critical distance method. The critical distance method is a simple way of voltage sag prediction based on the voltage divider rule. Generally, since this method is used for assessing radial systems, the concept of critical distances cannot be applied to meshed systems.

The second method is the fault positions method. The fault positions method can be applied to any type of system, however, there are problems of inaccuracy and inefficiency. In this method, many possible faults at arbitrary positions in the system are simulated to find positions at particular load buses that lead to voltages lower than the threshold. In the simulation, the positions are selected at random or selected so that the number of the positions in a predetermine section is proportional to a length of a line. Accuracy of this method depends on fault positions and the number of simulated faults. Because a large number of fault positions have to be simulated for more accurate sag prediction, this method is inefficient for large systems.

### SUMMARY OF THE INVENTION

The present invention provides a system and method which can rapidly perform calculation of the area of vulnerability and be applied to any type of system.

According to an aspect of the present invention, there is provided a system for determining the area of vulnerability for estimation of voltage sages, including: a system information reader reading information on a power system; a unit for determining the area of vulnerability calculating a voltages at a target bus corresponding to ends of a fault line by using the system information and a first residual voltage equation that is a voltage relationship between points in the fault line in the power system where a fault is simulated and the target bus where a voltage change due to the fault occurs, calculating a voltage at the target bus corresponding to a point between the ends when the voltages at the target bus corresponding to the ends are not higher than a predetermined voltage threshold, deriving a second residual voltage equation that is an approximate quadratic interpolation equation for the first residual voltage equation by using the voltages at the target bus corresponding to the ends and the point between the ends of the fault line, calculating the voltage of the target bus corresponding to the point of the fault line by using the second residual voltage equation, and determining the point of the fault line corresponding to a voltage of the target bus equal to or lower than the predetermined voltage threshold as the area of vulnerability; and a result output unit outputting results of the determination of the area of vulnerability.

The area of vulnerability is determined by using relationships between a voltage distribution on the target bus that is a sensitive load bus connected to a sensitive load and a voltage threshold, so that the calculation of the area of vulnerability can be rapidly and accurately performed and applied to any type of system.

The second residual voltage equation may be a quadratic interpolation equation of the first residual voltage equation, and a point between the ends of the fault line may be the center point between the ends.

When the voltage at the target bus is equal to the voltage threshold, a secant method may be used to calculate the point of the fault line. By using the secant method, the area of vulnerability can be rapidly and accurately determined.

According to another aspect of the present invention, there are provided a method performed in the system and a computer-readable medium having embodied thereon a computer program for the method.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic block diagram illustrating a system for determining the area of vulnerability for estimation of voltage sags according to the present invention;

FIG. 2 is a diagram illustrating a power system including a fault line and a target bus;

FIG. 3 is a schematic flowchart of a method of determining the area of vulnerability for estimation of voltage sags according to the present invention;

FIG. 4 is a detailed flowchart of the operation of determining the area of vulnerability in FIG. 3;

FIG. 5 is a view illustrating a simple power system;

FIG. 6 is a table of power flow calculation results of the power system illustrated in FIG. 5;

FIG. 7 is a graph of sag magnitudes and interpolation curves at a bus 5 due to faults on a line between buses 1 and 2;

FIG. 8 is a graph of sag magnitudes and interpolation curves at a bus 5 due to faults on a line between buses 1 and 3;

FIG. 9 is a table of results of calculating the area of vulnerability for a fifteenth bus in the IEEE-30 bus system; and

FIG. 10 is a view illustrating the calculation results of FIG. 9 applied to the power system.

### DETAILED DESCRIPTION OF THE INVENTION

Hereinafter, exemplary embodiments of the present invention will be described in detail with reference to the attached drawings.

FIG. 1 is a schematic block diagram illustrating a system for determining the area of vulnerability for estimation of voltage sags according to the present invention. Referring to FIG. 1, the system 100 for determining the area of vulnerability is connected to a power system 200 and a user terminal 300 and includes a system information reader 110, a unit 120 for determining the area of vulnerability, and a result output unit 130.

The system information reader 110 reads information on the power system 200. The unit 120 for determining the area of vulnerability determines information on the area of vulnerability for a predetermined line by using the system information. The result output unit 130 outputs a result of the determination the area of vulnerability performed by the unit 120 for determining the area of vulnerability to the user terminal 300.

A principle of the determination of the area of vulnerability performed by the unit 120 for determining the area of vulnerability is described as follows.

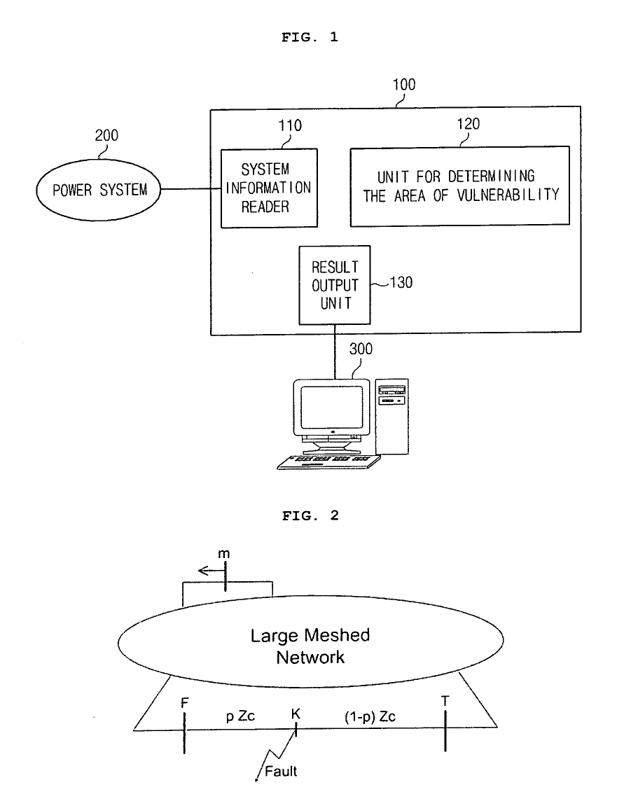

FIG. 2 is a diagram illustrating a power system including a fault line and a target bus. When there is a fault position K in a line F-T as illustrated in FIG. 2, a residual voltage equation of a bus m in a system due to the fault at the fault position K can be derived.

Since the voltage sag magnitude caused by an unbalanced fault has a different value according to a fault type and a phase, the determined area of vulnerability for the unbalanced fault is different according to a fault type and a phase.

Residual voltage equations for three-phase balanced faults and unbalanced faults including a single line-to-ground fault, a line-to-line fault, and a double line-to-ground fault can be derived.

In order to calculate each phase voltage of a sensitive load bus due to a fault on a line, the sequence transfer impedances between the sensitive load bus and the fault position, the sequence driving point impedances at the fault position, and the prefault voltage at the fault position have to be obtained.

The positive, negative, and zero sequence transfer impedances between the fault position K and the bus m can be expressed as follows. The superscripts 0, 1, and 2 represent the zero, positive, and negative phases, respectively.

Z_{mK}⁰=Z_{mF}⁰+(Z_{mT}⁰−Z_{mF}⁰)p

Z_{mK}¹=Z_{mF}¹+(Z_{mT}¹−Z_{mF}¹)p

Z_{mK}²=Z_{mF}²+(Z_{mT}²−Z_{mF}²)p

Here, Z_{mF}⁰¹² are the sequence transfer impedances corresponding to buses F and m, and Z_{mT}⁰¹² are the sequence transfer impedances corresponding to buses T and m. The parameter p is the value of the proportion of fault position to the length of a line (0≦p≦1).

The positive, negative, and zero sequence driving point impedances at the fault position K can be expressed as follows.

Z_{KK}⁰=(Z_{FF}⁰+Z_{TT}⁰−2Z_{FT}⁰−Z_{C}⁰)p²+{Z_{C}⁰−2(Z_{FF}⁰−Z_{FT}⁰)}p+Z_{FF}⁰

Z_{KK}¹=(Z_{FF}¹+Z_{TT}¹−2Z_{FT}¹−Z_{C}¹)p²+{Z_{C}¹−2(Z_{FF}¹−Z_{FT}¹)}p+Z_{FF}¹

Z_{KK}²=(Z_{FF}²+Z_{TT}²−2Z_{FT}²−Z_{C}²)p²+{Z_{C}²−2(Z_{FF}²−Z_{FT}²)}p+Z_{FF}²

Here, Z_{FF}⁰¹² are the sequence driving point impedances at the bus F, Z_{TT}⁰¹² are the sequence driving point impedances at the bus T, Z_{C}⁰¹² are the sequence impedances on the line, and Z_{TT}⁰¹² are the sequence transfer impedances between the buses F and T.

The prefault voltage at the fault position K is expressed as follows.

V_{K}^{pref}=V_{F}^{pref}+(V_{T}^{pref}−V_{F}^{pref})p

Here, V_{F}^{pref} and V_{F}^{pref} are the prefault voltages at the buses F and T.

The residual voltage equations for the unbalanced and balanced faults using the sequence impedances and the prefault voltages are obtained as follows.

1) Single Line-to-Ground Fault (SLGF)

When an SLGF occurs at phase A between the buses F and T on a line, a phase voltage at a sensitive load bus m can be expressed as follows.

$$\begin{matrix}{V}_{A , m}^{fault} = {V}_{A , m}^{pref} - \frac{{Z}_{mK}^{0} + {Z}_{mK}^{1} + {Z}_{mK}^{2}}{{Z}_{KK}^{0} + {Z}_{KK}^{1} + {Z}_{KK}^{2}} {V}_{K}^{pref} & Equation ( 1 ) \\ {V}_{B , m}^{fault} = {a}^{2} {V}_{A , m}^{pref} - \frac{{Z}_{mK}^{0} + {a}^{2} {Z}_{mK}^{1} + {aZ}_{mK}^{2}}{{Z}_{KK}^{0} + {Z}_{KK}^{1} + {Z}_{KK}^{2}} {V}_{K}^{pref} & Equation ( 2 ) \\ {V}_{C , m}^{fault} = {aV}_{A , m}^{pref} - \frac{{Z}_{mK}^{0} + {aZ}_{mK}^{1} + {a}^{2} {Z}_{mK}^{2}}{{Z}_{KK}^{0} + {Z}_{KK}^{1} + {Z}_{KK}^{2}} {V}_{K}^{pref} & Equation ( 3 )\end{matrix}$$

Here, V_{A,m}^{pref} is the prefault voltage at the bus m, and α is the complex number operator, e^{j120*}.

2) Line-to-Line Fault (LLF)

When an LLF occurs between phases B and C between buses F and T on a line, the phase voltages at a target bus m can be expressed as follows. Positive and negative sequences are considered for the voltage drop calculation caused by LLF.

$$\begin{matrix}{V}_{A , m}^{fault} = {V}_{A , m}^{pref} - \frac{{Z}_{mK}^{1} - {Z}_{mK}^{2}}{{Z}_{KK}^{1} + {Z}_{KK}^{2}} {V}_{K}^{pref} & Equation ( 4 ) \\ {V}_{B , m}^{fault} = {a}^{2} {V}_{A , m}^{pref} - \frac{{a}^{2} {Z}_{mK}^{1} - {aZ}_{mK}^{2}}{{Z}_{KK}^{1} + {Z}_{KK}^{2}} {V}_{K}^{pref} & Equation ( 5 ) \\ {V}_{C , m}^{fault} = {aV}_{A , m}^{pref} - \frac{{aZ}_{mK}^{1} - {a}^{2} {Z}_{mK}^{2}}{{Z}_{KK}^{1} + {Z}_{KK}^{2}} {V}_{K}^{pref} & Equation ( 6 )\end{matrix}$$

3) Double Line-to-Ground Fault (DLGF)

When a DLGF occurs at phases B and C between buses F and T on a line, the phase voltages at a target bus m can be expressed as follows.

$$\begin{matrix}{V}_{A , m}^{fault} = {V}_{A , m}^{pref} - \frac{\{ \begin{matrix}( {Z}_{mK}^{1} - {Z}_{mK}^{0} ) {Z}_{KK}^{2} + \\ ( {Z}_{mK}^{1} - {Z}_{mK}^{2} ) {Z}_{KK}^{0}\end{matrix} \}}{{Z}_{KK}^{0} {Z}_{KK}^{1} + {Z}_{KK}^{1} {Z}_{KK}^{2} + {Z}_{KK}^{2} {Z}_{KK}^{0}} {V}_{K}^{pref} & Equation ( 7 ) \\ {V}_{B , m}^{fault} = {a}^{2} {V}_{A , m}^{pref} - \frac{\{ \begin{matrix}( {a}^{2} {Z}_{mK}^{1} - {Z}_{mK}^{0} ) {Z}_{KK}^{2} + \\ ( {a}^{2} {Z}_{mK}^{1} - {aZ}_{mK}^{2} ) {Z}_{KK}^{0}\end{matrix} \}}{\begin{matrix}{Z}_{KK}^{0} {Z}_{KK}^{1} + {Z}_{KK}^{1} {Z}_{KK}^{2} + \\ {Z}_{KK}^{2} {Z}_{KK}^{0}\end{matrix}} {V}_{K}^{pref} & Equation ( 8 ) \\ {V}_{C , m}^{fault} = {aV}_{A , m}^{pref} - \frac{\{ \begin{matrix}( {aZ}_{mK}^{1} - {Z}_{mK}^{0} ) {Z}_{KK}^{2} + \\ ( {aZ}_{mK}^{1} - {a}^{2} {Z}_{mK}^{2} ) {Z}_{KK}^{0}\end{matrix} \}}{\begin{matrix}{Z}_{KK}^{0} {Z}_{KK}^{1} + {Z}_{KK}^{1} {Z}_{KK}^{2} + \\ {Z}_{KK}^{2} {Z}_{KK}^{0}\end{matrix}} {V}_{K}^{pref} & Equation ( 9 )\end{matrix}$$

4) Three Phase Fault (3PF)

When a three-phase fault occurs between buses F and T on a line, the phase voltage at a target bus m can be expressed as follows. Only positive sequence is considered for the voltage drop calculation caused by the three-phase fault.

$${V}_{m}^{fault} = {V}_{m}^{pref} - \frac{{Z}_{mK}^{1}}{{Z}_{KK}^{1}} {V}_{K}^{pref} \qquad Equation ( 10 )$$

The aforementioned residual voltage equations are related to p, and by using the derived equations, critical points p on a line F-T that lead to the voltage magnitude of a target bus m lower than a predetermined value can be calculated.

The p is referred to as a critical point. In unbalanced faults, the voltages in the faulted phases mainly drop whereas in the non-faulted phases remain more or less unchanged or rise. However, the voltages in non-faulted phases can be dropped due to transformer winding connections or differences between the sequence impedances.

For voltage sag analysis, only phases in which voltages drop are considered. Generally, the sag magnitudes at a target bus m due to faults that occur on a line F-T can be approximated to a quadratic curve for 0≦p≦1.

To find the critical points fast, it is assumed that up to two critical points on a line can exist and the voltage drops at a target bus m due to bus faults at ends of the line are higher than the voltage drops due to line faults on a line. In most of cases, the aforementioned conditions are satisfied. Some facts can be derived from the conditions as follows.

1) If the voltage threshold of a sensitive load is lower than the sag magnitude at both p=0 and p=1, this line is completely outside the area of vulnerability.

2) If the voltage threshold of a sensitive load is higher than the maximum magnitude of the residual voltage equation for a line, this line is completely inside the area of vulnerability.

3) If the voltage threshold of a sensitive load is a value between sag magnitudes at p=0 and p=1, there is one critical point on the line. One part of the line is inside the area of vulnerability.

4) If the voltage threshold of a sensitive load is lower than the maximum magnitude of the residual voltage equation for a line and higher than the sag magnitudes at both p=0 and p=1, there are two critical points on the line. Two parts of the line are inside the area of vulnerability.

Based on the four facts above and the residual voltage equations for all lines in a system, the accurate area of vulnerability can be determined.

The critical points on the lines can be found by using various methods. According to the present invention, the quadratic interpolation and the secant method are used. The methods can be applied to any type of system such as radial systems and meshed systems, and in the methods, the area of vulnerability can be rapidly and accurately calculated.

The secant method is one of numerical analysis methods for finding roots of non-linear equations. The secant method has a low convergence rate as compared with the Newton-Raphson method However, since there is no need to calculate differential values, the secant method is efficient when it is difficult to derive differential equations such as the residual voltage equations.

A general secant method for obtaining roots of a nonlinear equation f(x)=0 is expressed as follows.

1) Iteration loop (f(x): nonlinear equation, x_{from}, x_{end}: two starting values, x_{new}: new estimated value)

$${x}_{new} = {x}_{end} - \frac{f ( {x}_{end} ) ( {x}_{end} - {x}_{from} )}{f ( {x}_{end} ) - f ( {x}_{from} )}$$

$${x}_{from} = {x}_{end}$$

$${x}_{end} = {x}_{new}$$

2) Converge Estimation

|f(x_{new})|<tolerance

The general secant method is applied to the residual voltage equations as follows. Only the voltage magnitudes are considered for the calculation of the area of vulnerability, so that a magnitude of f(p), that is, |f(p)|=0 is an objective function.

Iteration Loop (f(p): residual voltage equation, p_{from}, p_{end}: two starting values, p_{new}: new estimated value)

$${p}_{new} = {p}_{end} - \frac{f ( {p}_{end} ) ( {p}_{end} - {p}_{from} )}{f ( {p}_{end} ) - f ( {p}_{from} )}$$

$${p}_{from} = {p}_{end}$$

$${p}_{end} = {p}_{new}$$

Converge Estimation

|f(p_{new})|<tolerance

This is the general secant method for finding roots of the residual voltage equation having the form of |f(p)|=0. In the method, a p that allows the magnitude of the residual voltage equation to be 0 is found.

However, in order to directly find roots without converting the residual voltage equation for a specific voltage threshold into the form of |f(p)|=0, the secant method may be modified as follows. Specifically, the secant method can be simply modified to be directly applied to the residual voltage equation having a form of |f(o)|=V_{threshold}. The modified secant method has an advantage in that various voltage thresholds can be directly applied without the conversion into |f(p)|=0.

Iteration Loop (f(p): residual voltage equation, p_{from}: p_{end}: two starting values, p_{new}: new estimated value)

$${p}_{new} = {p}_{end} - \frac{( \vert f ( {p}_{end} ) \vert - {V}_{threshold} ) ( {p}_{end} - {p}_{from} )}{\vert f ( {p}_{end} ) \vert - \vert f ( {p}_{from} ) \vert}$$

$${p}_{from} = {p}_{end}$$

$${p}_{end} = {p}_{new}$$

Converge Estimation

∥f(p_{new})|−V_{threshold}|<tolerance

The secant method has advantages as follows. There is no need to calculate differential values of the residual voltage equations to find roots. In addition, there is no need to convert the residual voltage equation into the form of |f(p)|=0, so that various voltage thresholds can be directly applied without the conversion of the equations.

However, two starting values are needed to find roots using the secant method. For fast finding, it is necessary to determine the starting values near the roots. For this, the quadratic interpolation for the residual voltage equation is used.

Examples of the quadratic interpolation include the Newton and Lagrange interpolation methods. The two methods each have advantages. However, since there is no difference between performances of the two methods in a low-order interpolation such as the quadratic interpolation, any one of the methods can be used. The quadratic interpolation is simply programmed for calculation. When it is assumed that the quadratic interpolation equation is V_{threshold}=apᵢ²+bpᵢ+c, the roots can be easily obtained by using the quadratic formula.

The aforementioned methods can be applied to three-phase balanced faults and unbalanced faults including a single line-to-ground fault, a line-to-line fault, and a double line-to-ground fault.

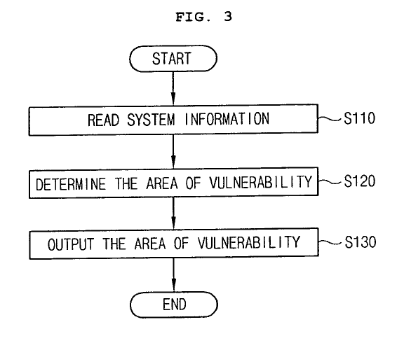

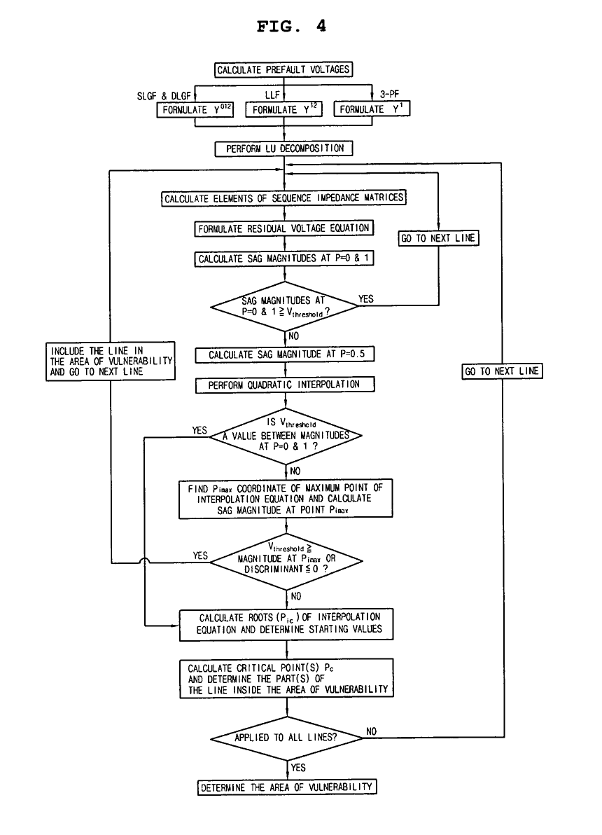

FIG. 3 is a schematic flowchart of a method of determining the area of vulnerability for estimation of voltage sags according to the present invention.

First, information on the power system targeted by the system for determining the area of vulnerability for the estimation of voltage sags is read (operation S110). Next, the area of vulnerability for a line targeted in the power system is determined by using the read system information (operation S120). Last, a result of the determination of the area of vulnerability is output to a predetermined output unit (operation S130).

FIG. 4 is a detailed flowchart of the operation of determining the area of vulnerability in FIG. 3. The order of calculating the area of vulnerability for a voltage threshold of a sensitive load bus of FIG. 4 is as follows.

1) Power flow analysis is performed to calculate prefault voltages in a system.

2) Positive, negative, and zero sequence admittance matrices corresponding to each fault type are formulated for the calculation, and the LU decomposition of the sequence admittance matrices is performed.

3) The elements of the sequence impedance matrices corresponding to the bus ends of a line are obtained by using forward and back substitution for the LU matrices.

4) The residual voltage equation is formulated by using results of 1) and 3).

5) The sag magnitudes at p=1 and p=1 are calculated by using the formulated residual voltage equation. If the voltage threshold is lower than the sag magnitudes at both p=0 and p=1, the line is completely outside the area of vulnerability, and operations from 3) are applied to a next line. If the voltage threshold is higher than the sag magnitudes at both p=0 and p=1, a next operation is performed.

6) The sag magnitude at p=0.5 is calculated by using the formulated residual voltage equation.

7) The quadratic interpolation is performed using the results at p=0, p=0.5, and p=1 calculated in operations 5) and 6). If the voltage threshold is a value between the sag magnitudes at p=0 and p=1, operation 9) is performed. If the voltage threshold is higher than the sag magnitudes at p=0 and p=1, a next operation is performed.

8) The maximum point P_{i,max} of the interpolation equation for 0≦P_{i,max}≦1 is calculated. The sag magnitude at the point P_{i,max} is calculated from the residual voltage equation. This sag magnitude is assumed to be the maximum value of the residual voltage equation. If the voltage threshold is higher than the maximum value or a discriminant of the quadratic interpolation equation is equal to or lower than 0, the line is completely inside the area of vulnerability, and operations from 3) are applied to a next line. If the voltage threshold is lower than the maximum value and higher than sag magnitudes at both p=0 and p=1, there are two critical points on the line.

9) Roots of the quadratic interpolation equation are calculated by using the quadratic formula. When the root of the interpolation equation is P_{ic}, two starting points are determined as P_{ic} and P_{ic}+Δp or P_{ic}−Δp and P_{ic}.

10) Critical points are calculated by using the starting points determined in operation 9) and the secant method.

11) Operations from 3) are applied to next lines. The operations above are applied to all lines.

12) The area of vulnerability is determined by using the calculated critical points.

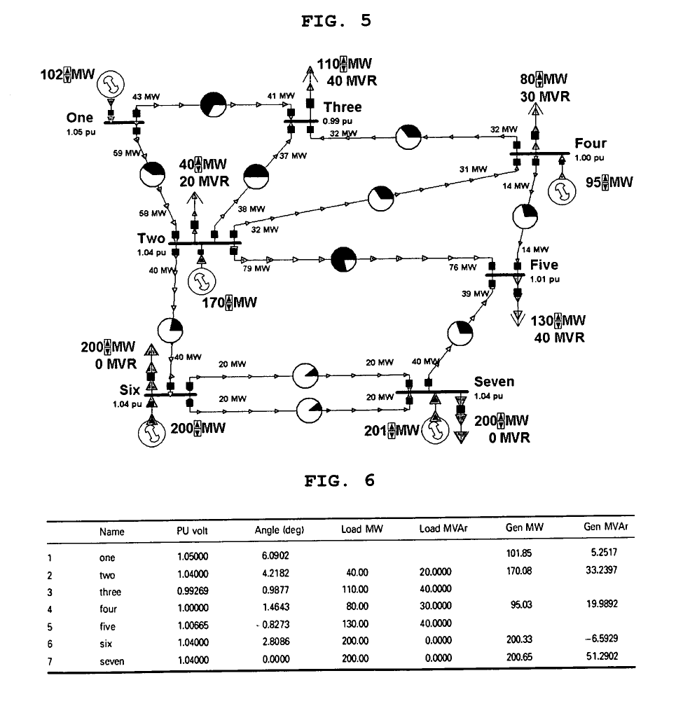

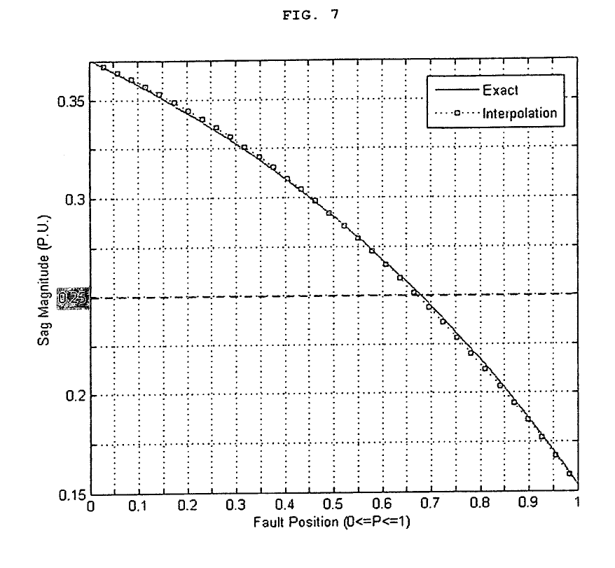

FIG. 5 is a view illustrating a simple 7 bus system for applying the method of determining the area of vulnerability for estimation of voltage sags according to the present invention, and FIG. 6 is a table of power flow calculation results of the power system illustrated in FIG. 5.

According to the current embodiment, the area of vulnerability of two lines for three-phase balanced faults is determined by applying the present invention. First, the area of vulnerability on a line between buses 1 and 2 is determined.

It is assumed that a sensitive load bus is the bus 5, and the voltage threshold is 0.25 p.u. A positive impedance of the line is Z_{C}¹=0.02+j0.06

Only positive sequence is considered for the three-phase balanced faults. The driving point impedances and the transfer impedances at buses 1 and 2 are calculated by the LU analysis. The results are as follows.

Z₁₁¹=0.0887+j0.1237=Z_{FF}¹, Z₂₂¹=0.0880+j0.0880=Z_{TT}¹

Z₂₂¹=Z₂₁¹=0.0787+j0.0815=Z_{FT}¹, Z₁₅¹=0.0766+j0.0585=Z_{mF}ⁱ=Z_{Fm}¹

Z₂₅¹=0.0814+j0.0613=Z_{mT}¹=Z_{Tm}¹, Vₘ^{pref}=V₅^{pref}=1.00665<−0.8273°

Equation (10) is applied by using the results above.

$$0.25 = \vert {V}_{5}^{pref} - \frac{{Z}_{5 K}^{1}}{{Z}_{KK}^{1}} {V}_{K}^{pref} \vert$$

Z_{KK}¹=(−0.0042−j0.0113)p²+(−j0.0244)p+(0.0887+j0.1237)

Z_{5K}¹=(0.0048+j0.0028)p+(0.0767+j0.0585)

V_{K}^{pref}=(−0.0069−j0.0349)p+(1.0441+j0.1114)

The sag magnitudes calculated by using the aforementioned equations at p=0 and p=1 are 0.3704 and 0.1533 p.u. The voltage threshold is 0.25 and is a value between the two sag magnitudes, so that there is one critical point on the line. The sag magnitude calculated at p=0.5 is 0.2903. The quadratic interpolation is performed by using the three values above. The interpolation equation is expressed as follows.

0.25=−0.1137pᵢ²−0.1034p₁+0.3704

The root p_{ic} that is calculated to satisfy 0≦p_{ic}≦1 by using the quadratic formula is only 0.6703.

FIG. 7 is a graph of sag magnitudes and the quadratic interpolation at the bus 5 due to the three-phase balanced faults on a line between buses 1 and 2.

The secant method is applied to find more accurate roots. The two starting values are set to p_{ic} and P_{ic}+0.001, respectively.

The critical point p_{c} accurately calculated by the secant method is 0.6771. Therefore, the area of vulnerability on the line is in a range of 0.6771≦p≦1. Specifically, a region from a point of about 67% of a length of the line to the end of the line is inside the area of vulnerability. The convergence error used for the calculation is 0.0001, and the calculated value converges on the root by repeating the calculation once. This means fast calculation.

Next, the area of vulnerability on the line between buses 1 and 3 is determined.

It is assumed that a sensitive load bus is a bus 7, and a voltage threshold is 0.5 p.u. A positive impedance of a line is Z_{C}¹=0.08+j0.24. The driving point impedances and the transfer impedances at buses 1 and 3 are calculated by the LU analysis. The results are as follows.

Z₁₁¹=0.0887+j0.1237=Z_{FF}¹, Z₃₃¹=0.0959+j0.1070=Z_{TT}¹

Z₁₃¹=Z₃₁¹=0.0787+j0.0737=Z_{FT}¹, Z₁₇¹=0.0752+j0.0522=Z_{mF}¹=Z_{Fm}¹

Z₃₇¹=0.0766+j0.0465=Z_{mT}¹=Z_{Tm}¹, Vₘ^{pref}=V₇^{pref}=1.04<0°

Equation (10) is applied by using the results above.

$$0.5 = \vert {V}_{7}^{pref} - \frac{{Z}_{5 K}^{1}}{{Z}_{KK}^{1}} {V}_{K}^{pref} \vert$$

$${Z}_{KK}^{1} = ( - 0.0511 - j 0.1568 ) {p}^{2} + ( 0.0583 + j 0.1401 ) p + ( 0.0887 + j 0.1237 )$$

$${Z}_{5 K}^{1} = ( 0.0014 - j 0.0057 ) p + ( 0.0752 + j 0.0522 )$$

$${V}_{K}^{pref} = ( - 0.0515 - j 0.0943 ) p + ( 1.0441 + j 0.1114 )$$

The sag magnitudes calculated by using the aforementioned equations at p=0 and p=1 are 0.4507 and 0.4758 p.u. The sag magnitude calculated at p=0.5 is 0.5956. The quadratic interpolation is performed by using the three values above. The interpolation equation is applied as follows.

0.5=−0.5290pᵢ²−0.5542pᵢ+0.4507

Since the voltage threshold is 0.5, the voltage threshold is higher than the sag magnitudes at p=0 and p=1. The maximum value P_{i,max} of the interpolation equation is 0.5238, and the sag magnitude is 0.5960 p.u. Therefore, there are two critical points on the line, and two parts of the line are inside the area of vulnerability.

The roots p_{ic1} and p_{ic2} that are calculated to satisfy 0≦p_{ic}≦1 by using the quadratic formula are 0.0981 and 0.9496, respectively.

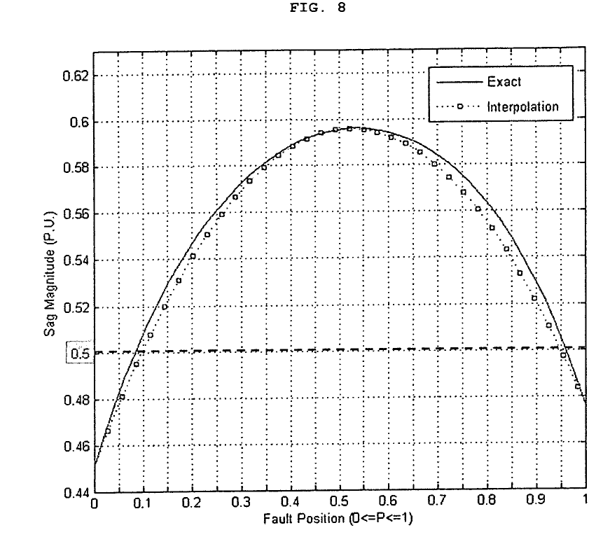

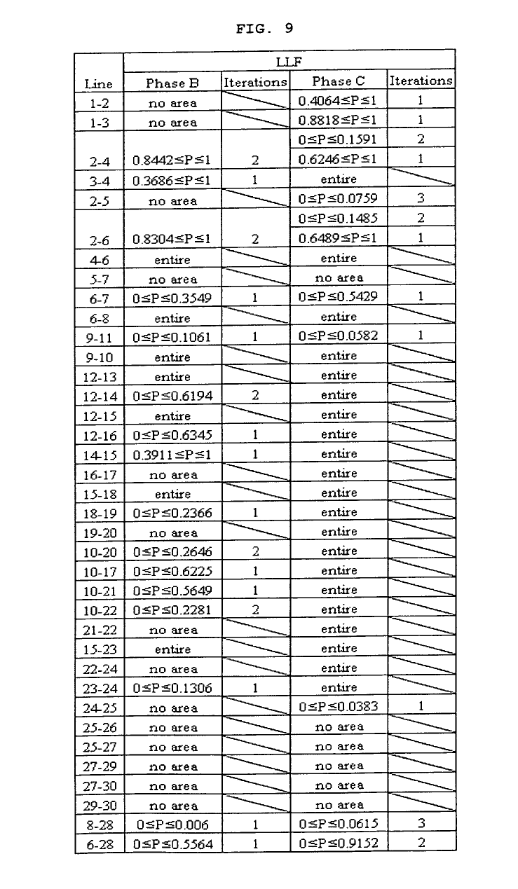

FIG. 8 is a graph of sag magnitudes and the quadratic interpolation at the bus 5 due to the three-phase balanced faults on a line between the buses 1 and 3.

The secant method is applied to find more accurate roots. The two starting values for the two roots p_{ic1} and p_{ic2} are set to p_{ic1} and p_{ic1}+0.001, and p_{ic2}−0.001 and p_{ic2}, respectively.

The critical points p_{ic1} and p_{ic2} accurately calculated by the secant method are 0.0841 and 0.9607. Therefore, the area of vulnerability on the line are in two ranges of 0≦p≦0.0841 and 0.9607≦p≦1. The convergence error used for the calculation is 0.0001, and the calculated values converge on the roots by repeating the calculation twice. This means fast calculation.

Last, the present invention is applied to the IEEE-30 bus system.

The IEEE-30 bus system includes 30 buses, 37 lines, and 4 transformers. A convergence error is set to 0.0001 for calculation. It is assumed that a target bus is a fifteenth bus, and a voltage threshold is 0.7 p.u. The positive, negative, and zero sequence internal impedances of all generators are j0.3, j0.2, and j0.05, respectively. All transformers's connections are assumed to be grounded wye-grounded wye. The fault is assumed to be LLF at phases B and C, and the area of vulnerability for the phases B and C is calculated. The area of vulnerability for the phase B and the area of vulnerability for the phase C are calculated by applying the residual voltage equations (5) and (6), respectively.

FIG. 9 is a table of results of calculating the area of vulnerability for the fifteenth bus in the IEEE-30 bus system. In the table illustrated in FIG. 9, the area of vulnerability and the number of repetitions of the secant method for each of the phases B and C are shown.

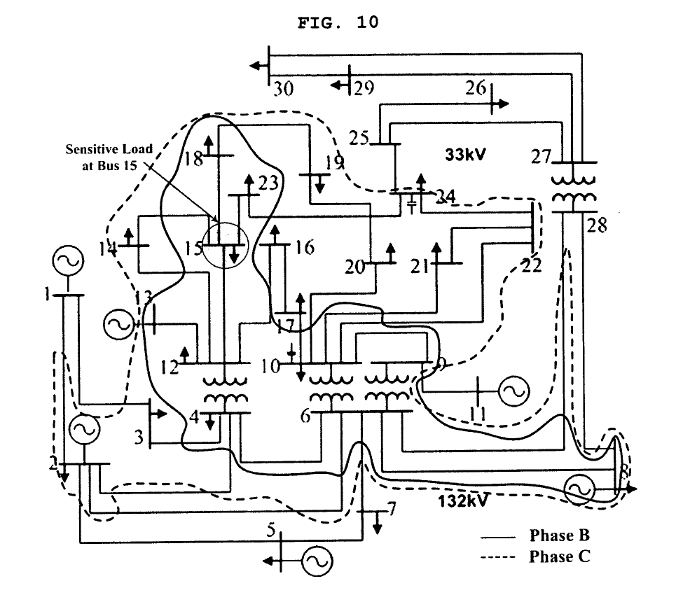

FIG. 10 is a view illustrating the calculation results of FIG. 9 applied to the power system. As illustrated by a full line and a dotted line in FIG. 10, it can be seen that the LLE generates a voltage sag at a fifteenth bus load.

As described above, the method of accurately and rapidly calculating the area of vulnerability is described. The method can be applied to unbalanced faults including a single line-to-ground fault, a line-to-line fault, and a double line-to-ground fault in addition to the three-phase balanced faults.

According to the present invention, the calculation of the area of vulnerability for estimation of voltage sags can be accurately and rapidly performed and applied to any type of system.

According to the present invention, the area of vulnerability for various voltage thresholds can be rapidly calculated by using only the quadratic interpolation equations and residual voltage equations.

While the present invention has been particularly shown and described with reference to exemplary embodiments thereof, it will be understood by those skilled in the art that various changes in form and details maybe made therein without departing from the spirit and scope of the present invention as defined by the appended claims.

What is claimed is:

1. A system for determining the area of vulnerability for estimation of voltage sages, comprising:
a system information reader reading information on a power system;
a unit for determining the area of vulnerability calculating a voltages at a target bus corresponding to ends of a fault line by using the system information and a first residual voltage equation that is a voltage relationship between points in the fault line in the power system where a fault is simulated and the target bus where a voltage change due to the fault occurs, calculating a voltage at the target bus corresponding to a point between the ends when the voltages at the target bus corresponding to the ends are not higher than a predetermined voltage threshold, deriving a second residual voltage equation that is an approximate quadratic interpolation equation for the first residual voltage equation by using the voltages at the target bus corresponding to the ends and the point between the ends of the fault line, calculating the voltage of the target bus corresponding to the point of the fault line by using the second residual voltage equation, and determining the point of the fault line corresponding to a voltage of the target bus equal to or lower than the predetermined voltage threshold as the area of vulnerability; and
a result output unit outputting results of the determination of the area of vulnerability.

2. The system of claim 1, wherein the point between the ends is the center point between the ends.

3. The system of claim 1, wherein, when the voltage at the target bus is equal to the predetermined voltage threshold, a secant method is used to calculate the point of the fault line.

4. A method of determining the area of vulnerability for estimation of voltage sages, comprising:
reading information on a power system targeted by a system for determining the area of vulnerability for estimation of voltage sages;
calculating a voltages at a target bus corresponding to ends of a fault line by using the system information and a first residual voltage equation that is a voltage relationship between points in the fault line in the power system where a fault is simulated and the target bus where a voltage change due to the fault occurs;
calculating a voltage at the target bus corresponding to a point between the ends when the voltages at the target bus corresponding to the ends are not higher than a predetermined voltage threshold;
deriving a second residual voltage equation that is an approximate quadratic interpolation equation for the first residual voltage equation by using the voltages at the target bus corresponding to the ends and the point between the ends of the fault line;
calculating the voltage of the target bus corresponding to the point of the fault line by using the second residual voltage equation;
determining the point of the fault line corresponding to a voltage of the target bus equal to or lower than the predetermined voltage threshold as the area of vulnerability; and
outputting results of the determination of the area of vulnerability.

5. The method of claim 4, wherein the point between the ends is the center point between the ends.

6. The method of claim 4, wherein, when the voltage at the target bus is equal to the predetermined voltage threshold, a secant method is used to calculate the point of the fault line.

7. A computer-readable medium having embodied thereon a computer program for a method of determining the area of vulnerability for estimation of voltage sages, comprising:
reading information on a power system targeted by a system for determining the area of vulnerability for estimation of voltage sages;
calculating a voltages at a target bus corresponding to ends of a fault line by using the system information and a first residual voltage equation that is a voltage relationship between points in the fault line in the power system where a fault is simulated and the target bus where a voltage change due to the fault occurs;
calculating a voltage at the target bus corresponding to a point between the ends when the voltages at the target bus corresponding to the ends are not higher than a predetermined voltage threshold;
deriving a second residual voltage equation that is an approximate quadratic interpolation equation for the first residual voltage equation by using the voltages at the target bus corresponding to the ends and the point between the ends of the fault line;
calculating the voltage of the target bus corresponding to the point of the fault line by using the second residual voltage equation;
determining the point of the fault line corresponding to a voltage of the target bus equal to or lower than the predetermined voltage threshold as the area of vulnerability; and
outputting results of the determination of the area of vulnerability.

8. The computer-readable medium of claim 7, wherein the point between the ends is the center point between the ends.

9. The computer-readable medium of claim 7, wherein, when the voltage at the target bus is equal to the predetermined voltage threshold, a secant method is used to calculate the point of the fault line.

10. A computer program for executing a method of determining the area of vulnerability for estimation of voltage sages, comprising:
reading information on a power system targeted by a system for determining the area of vulnerability for estimation of voltage sages;
calculating a voltages at a target bus corresponding to ends of a fault line by using the system information and a first residual voltage equation that is a voltage relationship between points in the fault line in the power system where a fault is simulated and the target bus where a voltage change due to the fault occurs;
calculating a voltage at the target bus corresponding to a point between the ends when the voltages at the target bus corresponding to the ends are not higher than a predetermined voltage threshold;
deriving a second residual voltage equation that is an approximate quadratic interpolation equation for the first residual voltage equation by using the voltages at the target bus corresponding to the ends and the point between the ends of the fault line;
calculating the voltage of the target bus corresponding to the point of the fault line by using the second residual voltage equation;
determining the point of the fault line corresponding to a voltage of the target bus equal to or lower than the predetermined voltage threshold as the area of vulnerability; and
outputting results of the determination of the area of vulnerability.

11. The computer program of claim 10, wherein the point between the ends is the center point between the ends.

12. The computer program of claim 10, wherein, when the voltage at the target bus is equal to the predetermined voltage threshold, a secant method is used to calculate the point of the fault line.
